(19) United States
(12) Patent Application Publication
(10) Pub. No.: US 2013/0163215 A1
(43) Pub. Date: Jun. 27, 2013

(54) ATTACHMENT MECHANISM FOR ELECTRONIC COMPONENT

(71) Applicant: ZHENG-HENG SUN, Tu-Cheng (TW)

(72) Inventor: ZHENG-HENG SUN, Tu-Cheng (TW)

(73) Assignee: HON HAI PRECISION INDUSTRY CO., LTD., Tu-Cheng (TW)

(21) Appl. No.: 13/434,791

(22) Filed: Mar. 29, 2012

(30) Foreign Application Priority Data
Dec. 24, 2011 (CN) 201110438370.X

(51) Int. Cl. H05K 7/14

(52) U.S. Cl. 361/759

(57) ABSTRACT

An attachment mechanism for an electronic component includes a circuit board and a fastener. The circuit board includes a connector to connect to the electronic component, and defines a mounting hole. The fastener includes a main body, two necks extending from the main body, and two cantilevers extending from the main body. Two resilient blocks extend from distal ends of each neck. The resilient blocks in a first end deformably extend through the mounting hole; thereby the resilient blocks in the first end abut against the circuit board after extending through the mounting hole. The resilient blocks in a second end deformably extend through the electronic component; thereby the resilient blocks in the second end abut against the electronic component after extending through the electronic component. Two hooks extend from distal ends of the cantilevers to hook the electronic component.

### CROSS-REFERENCE TO RELATED APPLICATIONS

Relevant subject matter is disclosed in two pending U.S. patent applications, both titled “ATTACHMENT MECHANISM FOR ELECTRONIC COMPONENT”, respectively filed on Mar. 22, 2012 and Mar. 23, 2012, with the application Ser. Nos. 13/426,629, and 13/427,923, which are assigned to the same assignee as this patent application.

### BACKGROUND

1. Technical Field

The present disclosure relates to a mechanism for attaching an electronic component to a device.

2. Description of Related Art

An electronic component, such as an expansion card, in an electronic device, is attached to a motherboard. An end of the expansion card is connected to the motherboard by a connector, and an opposite end of the expansion card is fastened to the motherboard with screws. Mounting the expansion card to the motherboard with screws is inefficient and requires the use of a tool, such as a screwdriver, which is inconvenient.

### BRIEF DESCRIPTION OF THE DRAWINGS

Many aspects of the present embodiments can be better understood with reference to the drawings. The components in the drawings are not necessarily drawn to scale, the emphasis instead being placed upon clearly illustrating the principles of the present embodiments. Moreover, in the drawings, all the views are schematic, and like reference numerals designate corresponding parts throughout the several views.

FIG. 1 is an exploded, isometric view of an exemplary embodiment of an attachment mechanism, wherein the attachment mechanism includes a fastener.

FIG. 2 is an enlarged view of the fastener of FIG. 1.

FIG. 3 is an assembled, isometric view of FIG. 1.

### DETAILED DESCRIPTION

The disclosure, including the accompanying drawings, is illustrated by way of example and not by way of limitation. It should be noted that references to “an” or “one” embodiment in this disclosure are not necessarily to the same embodiment, and such references mean at least one.

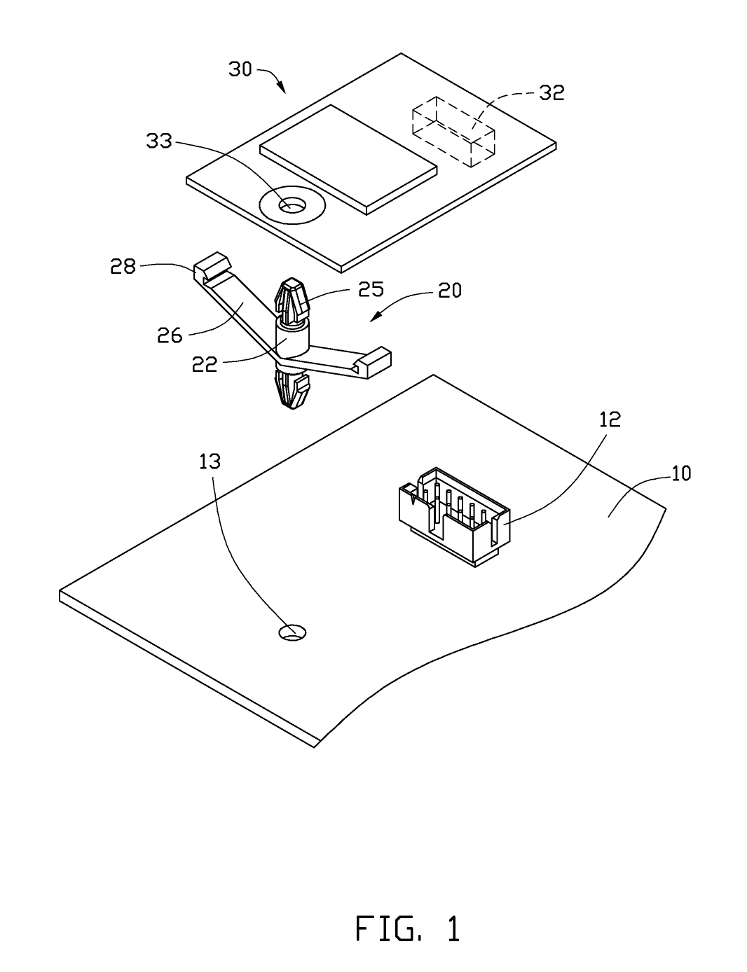

FIG. 1 shows an exemplary embodiment of an attachment mechanism for fastening an electronic component 30. The attachment mechanism includes a circuit board 10 and a fastener 20.

A first connector 12 is fastened to the circuit board 10. A mounting hole 13 is defined in the circuit board 10, beside the first connector 12.

A second connector 32 is fastened to a first end of a bottom surface of the electronic component 30. A through hole 33 is defined in a second end of the electronic component 30 opposite to the first end.

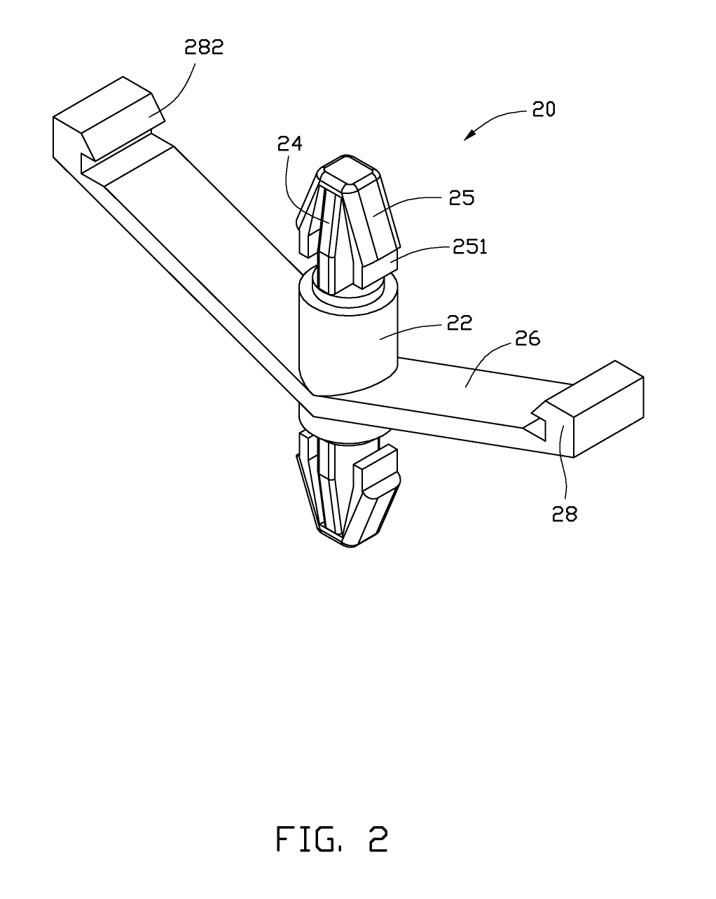

FIG. 2 shows the fastener 20 including a cylindrical main body 22, two cantilevers 26 slantingly extending up from opposite sides of a circumference of the main body 22 and two necks 24 extending from opposite ends of the main body 22. Two resilient blocks 25 slantingly extend from opposites sides of a distal end of each neck 24 toward the main body 22. An abutting block 251 extends from a distal end of each resilient block 24 toward the main body 22. Two L-shaped hook 28 extend from distal ends of the corresponding cantilevers 26. Each hook 28 extends up from the corresponding cantilever 26 and then extends toward the other hook 28. A guiding surface 282 is formed on a distal end of each hook 28 and faces the main body 22, slantingly extending down.

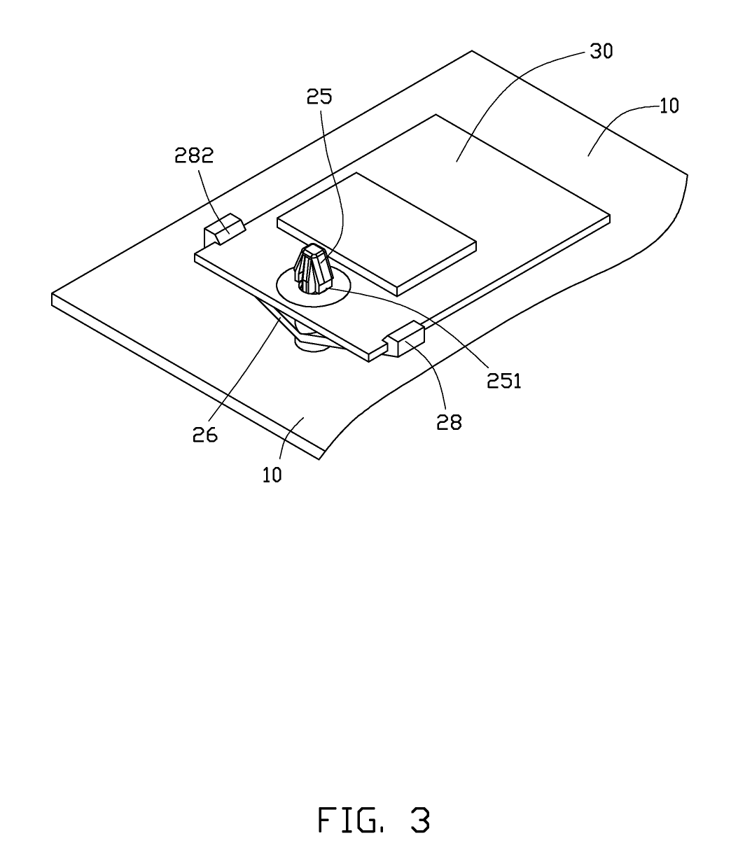

FIG. 3 shows in assembly, a bottom of the fastener 20 is inserted into the mounting hole 13. A sidewall bounding the mounting hole 13 biases the bottom resilient blocks 25 to be deformed toward each other. When the bottom abutting blocks 251 pass through the mounting hole 13, the bottom resilient blocks 25 are self-restored. The bottom abutting blocks 251 abut against a bottom surface of the circuit board 10. The bottom end surface of the main body 22 abuts against a top surface of the circuit board 10. Therefore, the fastener 20 is fastened to the circuit board 10.

To fasten the electronic component 30, the through hole 33 is aligned with the top resilient blocks 25. The electronic component 30 is manipulated down so that the top resilient blocks 25 and abutting blocks 251 are deformed by a sidewall bounding the through hole 33. After the top resilient blocks 25 and abutting blocks 251 pass through the through hole 33, the top resilient blocks 25 self-restore to make the top abutting blocks 251 abut against a top surface of the electronic component 30. Opposite sides of the electronic component 30 abut against the corresponding guiding surfaces 282. The cantilevers 26 with the hooks 28 are deformed away from each other. After the bottom surface of the electronic component 30 abuts against the top end surface of the main body 22, the hooks 28 engage with the corresponding sides of the electronic component 30. The second connector 32 is connected to the first connector 12. Therefore, the electronic component 30 is fastened to the attachment mechanism.

It is believed that the present embodiments and their advantages will be understood from the foregoing description, and various changes may be made thereto without departing from the spirit and scope of the description or sacrificing all of their materials advantages, the examples hereinbefore described merely being exemplary embodiments.

What is claimed is:

1. An attachment mechanism for fastening an electronic component, comprising:
a circuit board comprising a first connector to connect to a second connector of the electronic component, and defining a mounting hole; and
a fastener comprising a main body, two necks respectively extending from a first end and an opposite second end of the main body, and two cantilevers extending from opposite sides of the main body, two resilient blocks extending from distal ends of each neck, the resilient blocks of the neck at the first end operable to be deformed to extend through the mounting hole, thereby abutting against a bottom surface of the circuit board after passing through the mounting hole; the resilient blocks of the neck at the second end opposite to the first end operable to be deformed to extend through a through hole of the electronic component, thereby abutting against a top surface of the electronic component after passing through the through hole, two hooks respectively extending from distal ends of the cantilevers to hook opposite sides of the electronic component.

2. The attachment mechanism of claim 1, wherein the resilient blocks slantingly extend from the corresponding necks toward the main body.

3. The attachment mechanism of claim 1, wherein an abutting block extends from a distal end of each resilient block toward the main body, to abut against the corresponding circuit board or the corresponding electronic component.

4. The attachment mechanism of claim 1, wherein the cantilevers respectively and slantingly extend from the main body toward the electronic component.

5. The attachment mechanism of claim 1, wherein a slanting guiding surface is formed on a distal end of each hook and faces the main body.

6. A circuit board assembly, comprising:
a circuit board comprising a first connector and defining a mounting hole;
an electronic component comprising a second connector connected to the first connector, and defining a through hole; and
a fastener comprising a main body, two necks respectively extending from a first end and an opposite second end of the main body, and two cantilevers extending from opposite sides of the main body, two resilient blocks extending from distal ends of each neck, the resilient blocks of the neck at the first end operable to be deformed to extend through the mounting hole, thereby abutting against a bottom surface of the circuit board after passing through the mounting hole, the resilient blocks of the neck at the second end opposite to the first end operable to be deformed to extend through a through hole of the electronic component, thereby abutting against a top surface of the electronic component after passing through the through hole, two hooks respectively extending from distal ends of the cantilevers to hook opposite sides of the electronic component.

7. The circuit board assembly of claim 6, wherein the resilient blocks slantingly extend from the corresponding necks toward the main body.

8. The circuit board assembly of claim 6, wherein an abutting block extends from a distal end of each resilient block toward the main body, to abut against the corresponding circuit board or the corresponding electronic component.

9. The circuit board assembly of claim 6, wherein the cantilevers respectively and slantingly extend from the main body toward the electronic component.

10. The circuit board assembly of claim 6, wherein a slanting guiding surface is formed on a distal end of each hook and faces the main body.
